(19) United States
(12) Patent Application Publication
(10) Pub. No.: US 2009/0257182 A1
(43) Pub. Date: Oct. 15, 2009

(54) PORTABLE ELECTRONIC DEVICE WITH PROJECTION FUNCTION AND PROJECTION UNIT THEREOF

(75) Inventor: Ching-Fu Yang, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: COMPAL ELECTRONICS, INC., Taipei City (TW)

(21) Appl. No.: 12/272,733

(22) Filed: Nov. 17, 2008

(30) Foreign Application Priority Data
Apr. 9, 2008 (TW) 97112831

(51) Int. Cl. H05K 7/00

(52) U.S. Cl. 361/679.27; 361/679.01

(57) ABSTRACT

A portable electronic device with a projection function includes a host, a holder, and a projection module. The host has an opening at a side of the host. The display unit is pivoted to the host. The holder is movably disposed in the host and capable of being moved out from the opening of the host. The projection module is disposed on the holder for outputting an image light beam.

### CROSS-REFERENCE TO RELATED APPLICATION

This application claims the priority benefit of Taiwan application serial no. 97112831, filed on Apr. 9, 2008. The entirety of the above-mentioned patent application is hereby incorporated by reference herein and made a part of this specification.

### BACKGROUND OF THE INVENTION

1. Field of the Invention

The present invention relates to an electronic device and more particularly, to a portable electronic device with a projection function.

2. Description of Related Art

With advancement in projection display technology, there have been rapid development and significant breakthroughs in projection systems and equipment in recent years. Currently, there are three major types of projectors including cathode ray tubes (CRTs), high temperature polysilicon transmissive liquid crystal display panels (commonly referred to as liquid crystal projectors), and digital light source processors, wherein the liquid crystal projectors characterized by portability and easy adjustability are more frequently used by the public.

An operating principle of a projector is the same as that of a transparency or that of a slide, which uses a high-luminance lamp as a light source and projects content onto a white screen or a wall. All images of the projector are projected from a single lens in no need of adjusting the focus of the images. At present, the projector is often used to project and magnify an image on a transparency onto a white screen or a wall for purposes of propaganda, lecture, presentation, and so on. In addition, the projector can be further connected to a computer directly and project images on the computer onto a white screen or a wall, which saves the trouble of making transparencies and further promotes the practice of a paperless office.

However, in the current workplace, the projector is still often used together with a notebook computer in order to display an image on a computer screen onto a large screen or a wall for use in a conference or a demonstration. Consequently, transportation and storage of relevant projection equipment and the notebook computer as well as installation of connections between the projection equipment and the notebook computer result in problems including inconvenient usage as well as difficult and time-consuming installation.

### SUMMARY OF THE INVENTION

The present invention is directed to a portable electronic device that allows a user to use a projection module merely by extending a holder.

In the present invention, a portable electronic device including a host, a holder, and a projection module is provided. The host has an opening at a side of the host. The holder is movably disposed in the host and capable of being moved out from the opening of the host. The projection module is disposed on the holder for outputting an image light beam.

In one embodiment of the present invention, the holder disposed in the host is capable of being horizontally slid.

In one embodiment of the present invention, the holder disposed in the host is capable of being pivoted.

In one embodiment of the present invention, the portable electronic device further includes a linking rod. The linking rod has a first end and a second end. The first end is pivoted to the holder, and the second end is pivoted to the projection module.

In one embodiment of the present invention, one of the projection module and the second end of the linking rod has a bearing, and the other one of the projection module and the second end of the linking rod has an axle fitting the bearing.

In one embodiment of the present invention, the projection module has a first annular wave-shaped surface, and the second end of the linking rod has a second annular wave-shaped surface corresponding to the first annular wave-shaped surface to pivot stepwise the projection module relative to the second end of the linking rod.

In one embodiment of the present invention, the portable electronic device further includes a first component and a second component. The first component is disposed in the projection module. The second component is disposed at the second end of the linking rod. Here, the first component and the second component have a magnetic attraction force therebetween to force the first annular wave-shaped surface to contact the second annular wave-shaped surface.

In one embodiment of the present invention, at least one of the first component and the second component is a permanent magnet.

In one embodiment of the present invention, at least one of the first component and the second component is a magnetically sensitive component.

In one embodiment of the present invention, the host has an operation surface, a keyboard, and a cursor control module. The keyboard and the cursor control module are disposed on the operation surface.

In one embodiment of the present invention, the portable electronic device further includes a display unit. The display unit is pivoted to the host.

The present invention provides a projection unit adapted to be disposed in a portable electronic device. The projection unit including a holder and a projection module is provided. The holder is movably disposed in the portable electronic device. The projection module is disposed on the holder for outputting an image light beam.

In one embodiment of the present invention, the holder disposed in the portable electronic device is capable of being horizontally slid.

In one embodiment of the present invention, the holder disposed in the portable electronic device is capable of being pivoted.

In one embodiment of the present invention, the projection unit further includes a linking rod. The linking rod has a first end and a second end. The first end is pivoted to the holder, and the second end is pivoted to the projection module.

In one embodiment of the present invention, one of the projection module and the second end of the linking rod has a bearing, and the other one of the projection module and the second end of the linking rod has an axle fitting the bearing.

In one embodiment of the present invention, the projection module has a first annular wave-shaped surface, and the second end of the linking rod has a second annular wave-shaped surface corresponding to the first annular wave-shaped surface to pivot stepwise the projection module relative to the second end of the linking rod.

In one embodiment of the present invention, the projection unit further includes a first component and a second component. The first component is disposed in the projection module. The second component is disposed at the second end of the linking rod. Here, the first component and the second component have a magnetic attraction force therebetween to force the first annular wave-shaped surface to contact the second annular wave-shaped surface.

In one embodiment of the present invention, at least one of the first component and the second component is a permanent magnet.

In one embodiment of the present invention, at least one of the first component and the second component is a magnetically sensitive component.

When a user needs to use the projection module of the present invention, the projection module on the holder in the host can be moved out and used only by extending the holder. Thereby, it is more convenient for the user to project an image of the display unit by using the projection module without additionally purchasing a conventional projector, such that troublesome installation of circuits connected between the conventional projector and the electronic device can be prevented.

In order to make the above and other features and advantages of the present invention more comprehensible, several embodiments accompanied with figures are described in detail below.

### BRIEF DESCRIPTION OF THE DRAWINGS

FIG. 1A is a schematic view of a portable electronic device with a projection function according to one embodiment of the present invention.

FIG. 1B is a schematic view in which the projection module depicted in FIG. 1A stands on a holder by means of linking rods.

FIG. 2A is a partial enlarged cross-sectional view of the projection module and one of the linking rods depicted in FIG. 1A.

FIG. 2B is a schematic partial enlarged view of the projection module and the linking rods depicted in FIG. 1B.

FIG. 2C is a schematic view of the projection module and one of the linking rods depicted in FIG. 2B from another viewing angle.

FIG. 3A is a schematic view of a portable electronic device with a projection function according to another embodiment of the present invention.

FIG. 3B is a schematic view in which the projection module depicted in FIG. 3A stands on a holder by means of linking rods.

### DESCRIPTION OF EMBODIMENTS

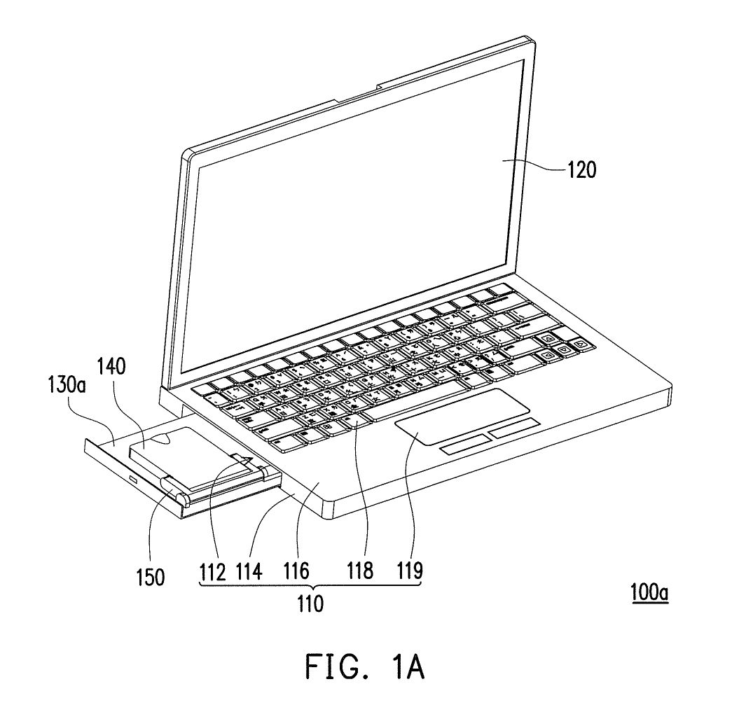

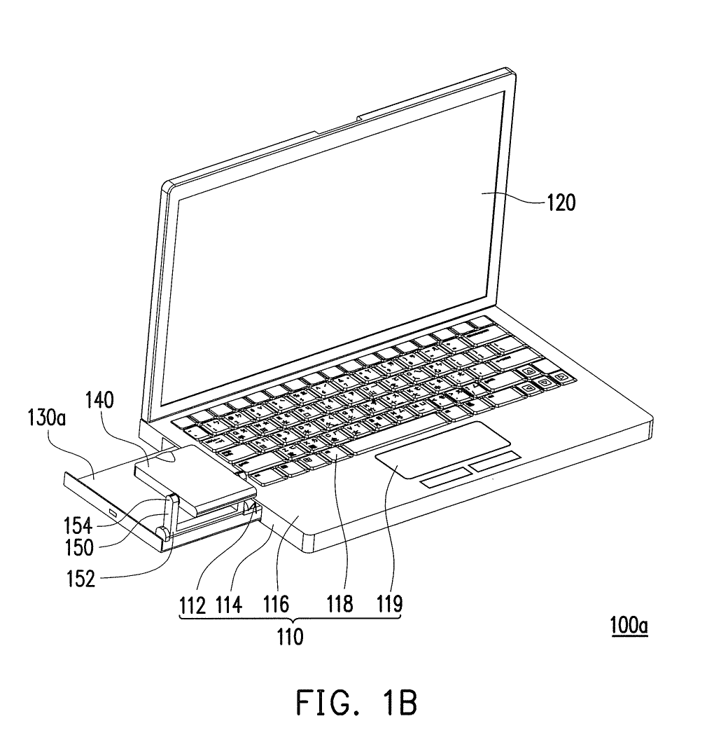

FIG. 1A is a schematic view of a portable electronic device with a projection function according to one embodiment of the present invention. Referring to FIG. 1A, in the present embodiment, a portable electronic device 100a includes a host 110, a display unit 120, a holder 130a, and a projection module 140. Here, the portable electronic device 100a is, for example, a notebook computer.

Specifically, the host 110 has an opening 112 at a side 114 of the host 110. The holder 130a is movably disposed in the host 110 and capable of being moved out from the opening 112 of the host 110. The holder 130a which can support the projecton module 140, such as a tray or a frame. Besides, the host 110 has an operation surface 116, a keyboard 118, and a cursor control module 119. The keyboard 118 and the cursor control module 119 are disposed on the operation surface 116. In this embodiment, a cursor control module 119 which can control the movement of the cursor, such as a touch pad, a touch panel or a track ball, etc. The display unit 120 is pivoted to the host 110. The projection module 140 is disposed on the holder 130a for outputting an image light beam.

Note that the holder 130a disposed in the host 110 can be horizontally slid according to the present embodiment. Hence, when a user needs to use the projection module 140, the projection module 140 on the holder 130a in the host 110 can be moved out and used only by extending the holder 130a. In addition, images of the display unit 120 can be projected by using the projection module 140.

FIG. 1B is a schematic view in which the projection module depicted in FIG. 1A stands on the holder by means of linking rods. Referring to FIG. 1B, in the present embodiment, the portable electronic device 100a further includes two linking rods 150. Each of the linking rods 150 has a first end 152 and a second end 154. The first end 152 is pivoted to the holder 130a, and the second end 154 is pivoted to the projection module 140. That is to say, the linking rods 150 connect the holder 130a to the projection module 140.

In particular, by extending the holder 130a of the portable electronic device 100a, the projection module 140 can be moved out of the host 110. Thereby, a user may more easily and conveniently make use of the projection module 140 without needing to additionally purchase a conventional projector, such that troublesome installation of circuits connected between the conventional projector and the electronic device can be prevented. At the same time, an application range of the portable electronic device 100a can be expanded.

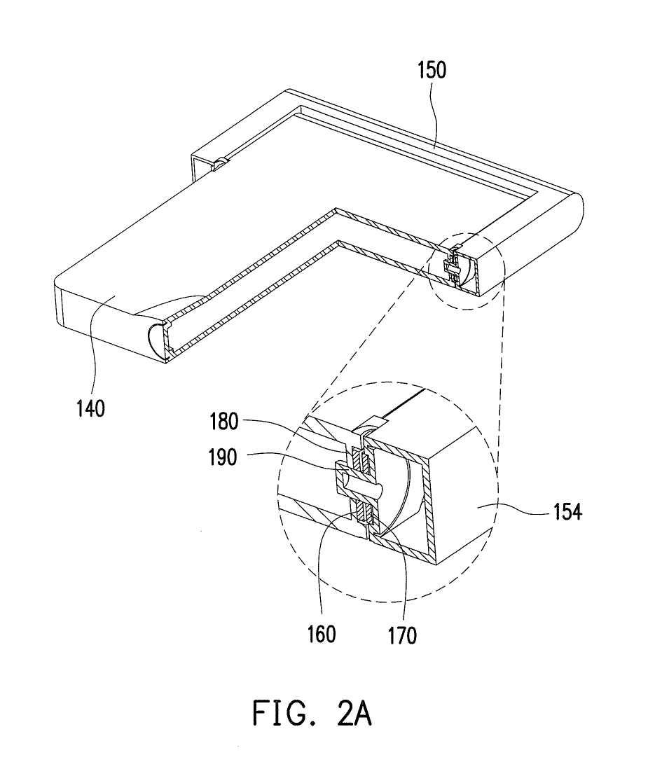

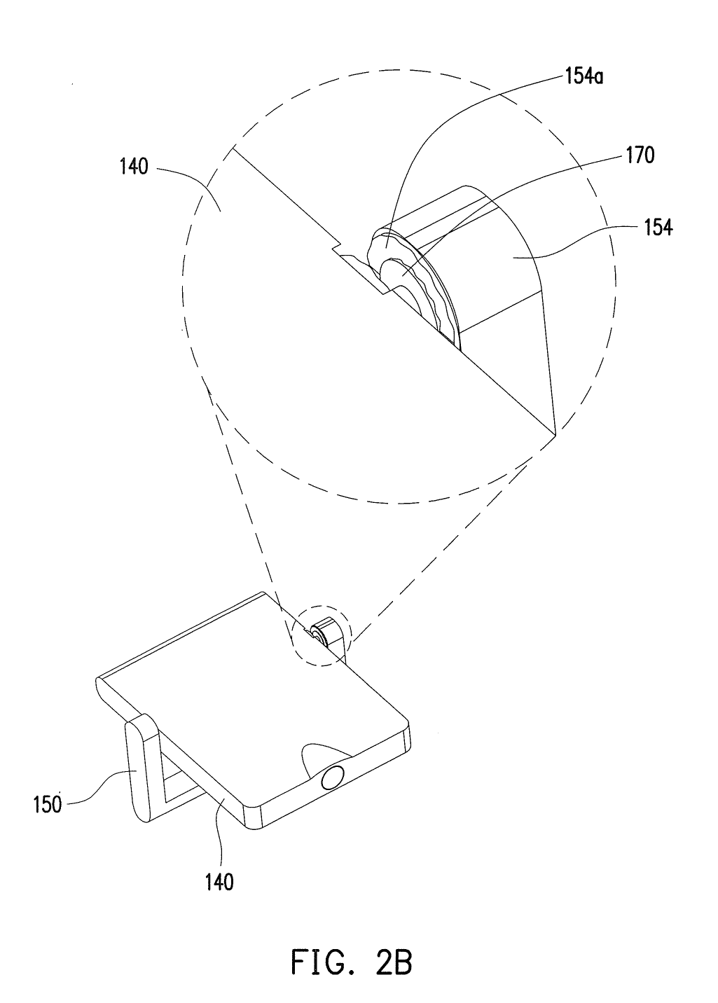

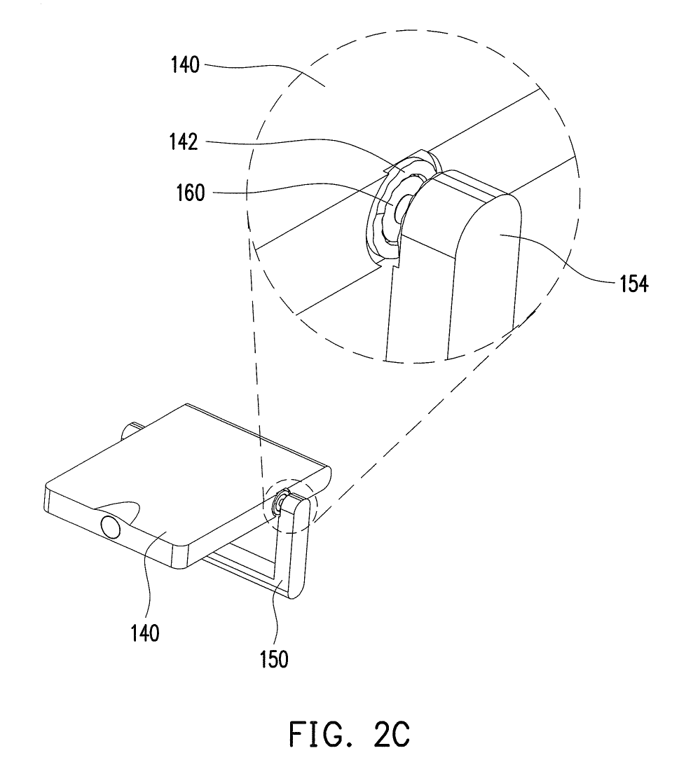

FIG. 2A is a partial enlarged cross-sectional view of the projection module and one of the linking rods depicted in FIG. 1A. Referring to FIG. 2A, in the present embodiment, the projection module 140 has a bearing 180, and the second end 154 of each of the linking rods 150 has an axle 190 fitting the bearing 180. Here, the bearing 180 is utilized for keeping the axle 190 to be centrally positioned.

It should be mentioned that the positions of the bearing 180 and the axle 190 are not limited to those described in the present invention. In another embodiment, the second end 154 of each of the linking rods 150 may be equipped with the bearing 180, and the projection module 140 may have the axle 190 fitting the bearing 180, which still belongs to a technical means adoptable in the present invention and falls within the protection scope of the present invention.

FIG. 2B is a schematic partial enlarged view of the projection module and the linking rods depicted in FIG. 1B. FIG. 2C is a schematic view of the projection module and one of the linking rods depicted in FIG. 2B from another viewing angle. Referring to FIGS. 2B and 2C, in the present embodiment, the projection module 140 has a first annular wave-shaped surface 142, and the second end 154 of the linking rod 150 has a second annular wave-shaped surface 154a corresponding to the first annular wave-shaped surface 142 to pivot stepwise the projection module 140 relative to the second end 154 of the linking rod 150.

In addition, in the present embodiment, the portable electronic device 100a further includes a first component 160 and a second component 170. The first component 160 is disposed in the projection module 140. The second component 170 is disposed at the second end 154 of the linking rod 150. Here, the first component 160 and the second component 170 have a magnetic attraction force therebetween to force the first annular wave-shaped surface 142 to contact the second annular wave-shaped surface 154a.

Note that the first component 160 is a permanent magnet and the second component 170 is a magnetically sensitive component according to the present embodiment. However, the present invention does not limit the types of the first component 160 and the second component 170. In another embodiment, the second component 170 may be a permanent magnet and the first component 160 may be a magnetically sensitive component, which still belongs to a technical means adoptable in the present invention and falls within the protection scope of the present invention.

In detail, the magnetic attraction force between the first component 160 and the second component 170 forces the first annular wave-shaped surface 142 to contact the second annular wave-shaped surface 154a. Besides, a pivot angle of the projection module 140 relative to the second end 154 of each of the linking rods 150 is adjusted by pivoting the first annular wave-shaped surface 142 relative to the second annular wave-shaped surface 154a.

Namely, the pivot angle of the projection module 140 relative to the linking rods 150 can be adjusted stepwise. Additionally, a user is able to adjust a position of a projected image by pivoting the projection module 140 relative to the linking rod 150. Thereby, the projection module 140 can be used in a relatively simple and easy manner.

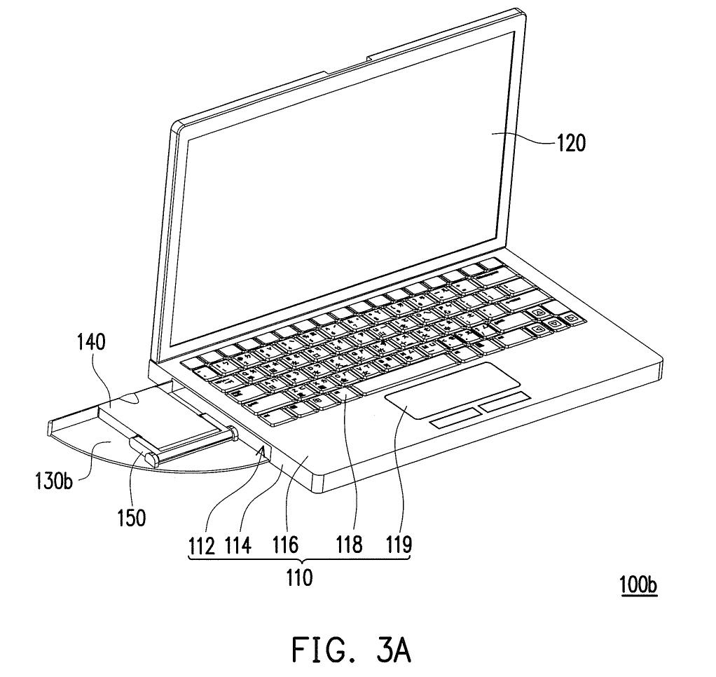

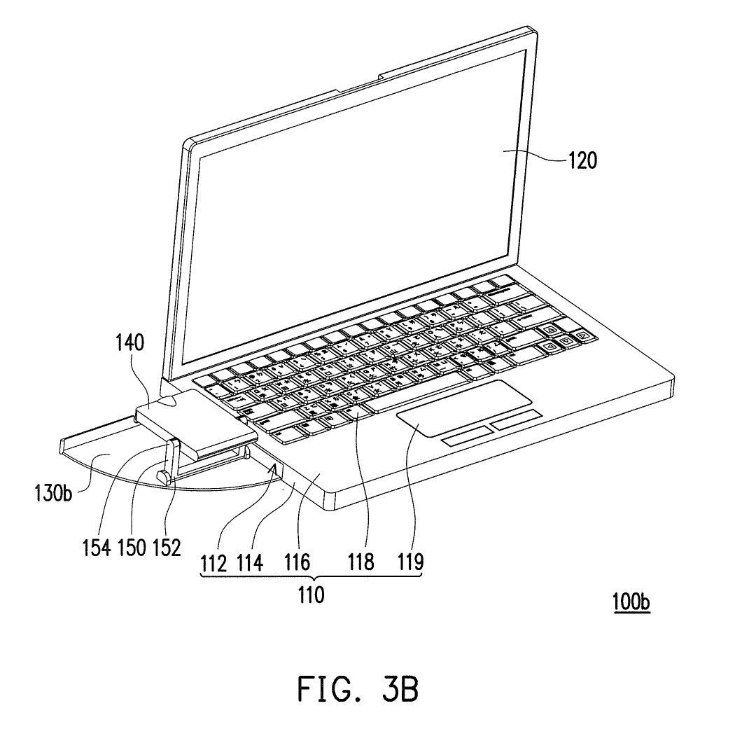

FIG. 3A is a schematic view of a portable electronic device with a projection function according to another embodiment of the present invention. Referring to FIG. 3A, in the present embodiment, a portable electronic device 100b includes a host 110, a display unit 120, a holder 130b, and a projection module 140. Here, the portable electronic device 100b is, for example, a notebook computer.

Specifically, the host 110 has an opening 112 at a side 114 of the host 110. The holder 130b is movably disposed in the host 110 and capable of being moved out from the opening 112 of the host 110. Besides, the host 110 has an operation surface 116, a keyboard 118, and a cursor control module 119. The keyboard 118 and the cursor control module 119 are disposed on the operation surface 116. The display unit 120 is pivoted to the host 110. The projection module 140 is disposed on the holder 130b for outputting an image light beam.

Note that the holder 130b disposed in the host 110 is capable of being pivoted according to the present embodiment. Here, the holder 130b is, for example a quarter disk. Accordingly, when a user needs to use the projection module 140, the projection module 140 on the holder 130b in the host 110 can be moved out and used only by extending the holder 130b.

FIG. 3B is a schematic view in which the projection module depicted in FIG. 3A stands on the holder by means of linking rods. Referring to FIG. 3B, in the present embodiment, the portable electronic device 100b further includes two linking rods 150. Each of the linking rods 150 has a first end 152 and a second end 154. The first end 152 is pivoted to the holder 130b, and the second end 154 is pivoted to the projection module 140. That is to say, the linking rods 150 connect the holder 130b to the projection module 140.

Moreover, the correlations among components of the linking rods 150, the holder 130b, and the projection module 140 are similar to those described in the previous embodiment indicated in FIGS. 2A, 2B, and 2C, and therefore no further description is provided herein.

In brief, by extending the holder 130b of the portable electronic device 100b, the projection module 140 on the holder 130b can be moved out of the host 110, and a pivot angle of the projection module 140 relative to the linking rods 150 can be adjusted stepwise. Additionally, a user is able to adjust a position of a projected image by pivoting the projection module 140 relative to the linking rods 150, so as to project the image displayed on the display unit 120.

Based on the above, it is easy and convenient for a user to use the projection module 140 without additionally purchasing a conventional projector, such that troublesome installation of circuits connected between the conventional projector and the electronic device can be prevented, and the portable electronic device 100b can be applied more extensively.

In light of the foregoing, when a user needs to use the projection module of the present invention, the projection module on the holder in the host can be moved out and used only by extanding the holder. Additionally, a position of a projected image can be adjusted by pivoting the projection module relative to the linking rods, so as to utilize the project module in an easy and convenient manner.

Moreover, the present invention not only expands the application range of the portable electronic device but also provides a more convenient tool for use during conferences or demonstration. It is neither necessary to additionally purchase a conventional projector nor required to install the circuits connecting the conventional projector to an electronic device, thus giving rise to reduced costs and efficient space utilization.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A portable electronic device with a projection function, comprising:
a host, having an opening at a side of the host;
a holder, movably disposed in the host, wherein the holder is capable of being moved out from the opening of the host; and
a projection module, disposed on the holder for outputting an image light beam.

2. The portable electronic device with the projection function as claimed in claim 1, wherein the holder disposed in the host is capable of being horizontally slid.

3. The portable electronic device with the projection function as claimed in claim 1, wherein the holder disposed in the host is capable of being pivoted.

4. The portable electronic device with the projection function as claimed in claim 1, further comprising:
a linking rod, having a first end and a second end, wherein the first end is pivoted to the holder, and the second end is pivoted to the projection module.

5. The portable electronic device with the projection function as claimed in claim 4, wherein one of the projection module and the second end of the linking rod has a bearing, and the other one of the projection module and the second end of the linking rod has an axle fitting the bearing.

6. The portable electronic device with the projection function as claimed in claim 4, wherein the projection module has a first annular wave-shaped surface, and the second end of the linking rod has a second annular wave-shaped surface corresponding to the first annular wave-shaped surface to pivot stepwise the projection module relative to the second end of the linking rod.

7. The portable electronic device with the projection function as claimed in claim 6, further comprising:
a first component, disposed in the projection module; and
a second component, disposed at the second end of the linking rod,
wherein the first component and the second component have a magnetic attraction force therebetween to force the first annular wave-shaped surface to contact the second annular wave-shaped surface.

8. The portable electronic device with the projection function as claimed in claim 7, wherein at least one of the first component and the second component is a permanent magnet.

9. The portable electronic device with the projection function as claimed in claim 8, wherein at least one of the first component and the second component is a magnetically sensitive component.

10. The portable electronic device with the projection function as claimed in claim 1, wherein the host has an operation surface, a keyboard, and a cursor control module, and the keyboard and the cursor control moduleare disposed on the operation surface.

11. The portable electronic device with the projection function as claimed in claim 1, further comprising:
a display unit, pivoted to the host.

12. A projection unit, suitable for being disposed in a portable electronic device, the projection unit comprising:
a holder, movably disposed in the portable electronic device; and
a projection module, disposed on the holder for outputting an image light beam.

13. The projection unit as claimed in claim 12, wherein the holder disposed in the portable electronic device is capable of being horizontally slid.

14. The projection unit as claimed in claim 12, wherein the holder disposed in the portable electronic device is capable of being pivoted.

15. The projection unit as claimed in claim 12, further comprising:
a linking rod, having a first end and a second end, wherein the first end is pivoted to the holder, and the second end is pivoted to the projection module.

16. The projection unit as claimed in claim 15, wherein one of the projection module and the second end of the linking rod has a bearing, and the other one of the projection module and the second end of the linking rod has an axle fitting the bearing.

17. The projection unit as claimed in claim 15, wherein the projection module has a first annular wave-shaped surface, and the second end of the linking rod has a second annular wave-shaped surface corresponding to the first annular wave-shaped surface to pivot stepwise the projection module relative to the second end of the linking rod.

18. The projection unit as claimed in claim 17, further comprising:
a first component, disposed in the projection module; and
a second component, disposed at the second end of the linking rod,
wherein the first component and the second component have a magnetic attraction force therebetween to force the first annular wave-shaped surface to contact the second annular wave-shaped surface.

19. The projection unit as claimed in claim 18, wherein at least one of the first component and the second component is a permanent magnet.

20. The projection unit as claimed in claim 19, wherein at least one of the first component and the second component is a magnetically sensitive component.
